(19) United States
(12) Patent Application Publication
(10) Pub. No.: US 2008/0102648 A1
(43) Pub. Date: May 1, 2008

(54) Method and System For Making Photo-Resist Patterns

(75) Inventors: Chin-Hsiang Lin, Hsin-Chu (TW); Hsiao-Tzu Lu, Hsinchu (TW); Kuei Shun Chen, Hsin-Chu (TW); Ching-Yu Chang, Yilang County (TW); Vencent Chang, Hsin-Chu (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/555,558

(22) Filed: Nov. 1, 2006

(51) Int. Cl. H01L 21/302; G03G 13/10

(52) U.S. Cl. 438/745; 438/750; 430/117.1

(57) ABSTRACT

A method of forming a resist pattern in a semiconductor device layer includes forming a buffer layer on a semiconductor device layer and forming a resist layer on the buffer layer. A decomposing agent is released into a portion of the buffer layer by a portion of the resist layer whereupon the portion of the buffer layer and the portion of the resist layer are removed to form a process window substantially free of resist residue that can be subsequently exploited for etching of the semiconductor device layer.

### BACKGROUND

The present disclosure relates in general to semiconductor fabrication and, more particularly, to a method and system for patterning photo-resists with reduced footing and scum residue.

In integrated circuit (IC) manufacturing technology, a resist layer is typically applied to a semiconductor wafer surface, followed by exposure of the resist through a mask. A post-exposure baking process and a developing process are then performed to form a patterned resist layer with openings. After verification that the resist is within fabrication specifications, the wafer is etched to remove portions of the wafer exposed through the openings. Following etching of the wafer, the resist layer is stripped.

In conventional resist patterning, it is not uncommon for a photo-resist footing and/or residual scum to be present in the openings of the patterned resist layer. That is, the photo-resist patterning and developing process commonly leaves a residue in the openings. This residue can narrow the resist opening as well as negatively affect the accuracy of critical dimension (CD) measurements and disturb etching bias tuning.

It would therefore be desirable to have a method and system of patterning and developing a photo-resist layer on a semiconductor wafer substantially free of photo-resist footing, scum, and/or other undesirable photo-resist residue.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flow chart of one embodiment of a method to form an integrated circuit (IC).

FIGS. 2-5 illustrate patterning of an IC according to one embodiment of the present disclosure.

### DETAILED DESCRIPTION

For the purposes of promoting an understanding of the principles of the invention, reference will now be made to the embodiments, or examples, illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates. Furthermore, the depiction of one or more elements in close proximity to each other does not otherwise preclude the existence of intervening elements. Also, reference numbers may be repeated throughout the embodiments, and this does not by itself indicate a requirement that features of one embodiment apply to another embodiment, even if they share the same reference number.

Disclosed is a method of patterning a semiconductor substrate or other device layer substantially free of resist residue. In this regard, the disclosed method reduces the presence of resist footings and/or scum layers in the openings of a patterned resist layer. The disclosed method includes application of a buffer layer that is applied to a top surface of a substrate followed by application of a resist layer on the buffer layer. Portions of the buffer and resist layers are removed simultaneously during a developing process to define various openings in the resist layer and buffer layer.

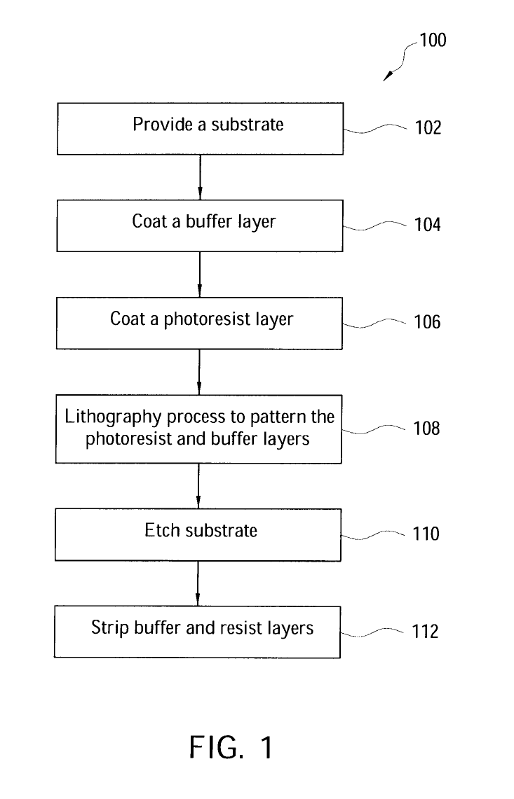

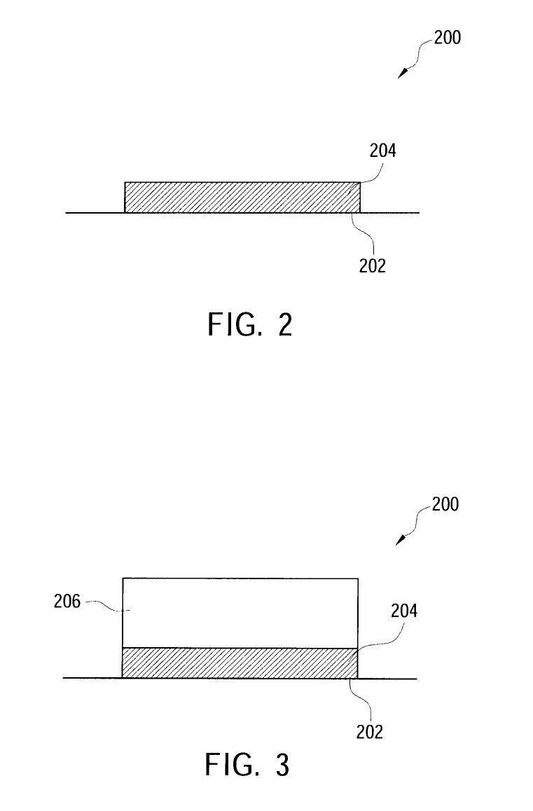

FIG. 1 is a flowchart of one embodiment of a method 100 to form an integrated circuit (IC). FIGS. 2-5 illustrate sectional views of an exemplary IC 200 during various fabrication stages and made by the method 100. One skilled in the art will readily appreciate the fabrication of an IC in accordance with the present disclosure may include fabrication steps in addition to those illustrated in the method 100 of FIG. 1.

The method 100 begins at step 102 by providing a substrate 202 or other base layer, as illustrated in FIG. 2. The invention will be described with respect to patterning a substrate, but may also be used to pattern other semiconductor device layers. Therefore, reference to “base layer” shall include any semiconductor device layer capable of being patterned. The substrate 202 includes silicon. Alternatively, the substrate 202 may include other elementary semiconductor such as germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. The substrate 202 may include an epitaxial layer. For example, the substrate may have an epitaxial layer overlying a bulk semiconductor. Furthermore, the substrate 202 may include a semiconductor-on-insulator (SOI) structure. For examples, the substrate may include a buried oxide (BOX) layer formed by a process such as separation by implanted oxygen (SIMOX). The substrate 202 may include various p-type doped regions and/or n-type doped regions, implemented by a process such as ion implantation and/or diffusion. The substrate 202 may include other functional features such as resistor, capacitor, and gate structure. The substrate 202 may include lateral isolation features disposed to separate various devices formed on the substrate 202. The substrate 202 may further at least partially include a plurality of patterned dielectric layers and patterned conductive layers combined to form interconnections configured to couple the various p-type and n-type doped regions and the other functional features. For example, the substrate 202 may include a portion of a multi-layer interconnect (MLI) structure and an inter-level dielectric (ILD) disposed in the MLI structure.

The substrate 202 may also include a material layer (not shown) formed thereon that includes a dielectric material such as silicon oxide, silicon nitride, a low dielectric constant (low k) material, or a combination thereof. The low k material may include fluorinated silica glass (FSG), carbon doped silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other materials as examples. A process of forming the material layer may utilize chemical vapor deposition (CVD) or a spin-on coating.

The method 100 proceeds to step 104 by depositing a buffer layer 204 on the substrate 202. The buffer layer, in a manner similar to formation of a resist layer, may be formed using spin-on coating or other applicable technique. The buffer layer may include a bottom anti-reflection layer (BARC) or component. One or more adhesion layers may be formed on the top and bottom surfaces of the BARC layer to enhance adhesion between the buffer layer 204 and the substrate 202 and a resist layer 206, FIG. 3. In another embodiment, an adhesion layer and a BARC layer may be combined into one layer to function for both purposes. A baking process may be implemented after forming the adhesion layer(s) and/or BARC layer. Also, buffer layer 204 is relatively thin. For example, the buffer layer 204 has a thickness in the range of 10 to 300 Angstroms and, in one preferred example, has a thickness of 30-100 Angstroms

The method 100 continues to step 106 with coating of a photoresist (resist) layer 206 on the buffer layer 204, as illustrated in FIG. 3. The photoresist layer 206 and the buffer layer 204 are formed or comprised of materials that are incompatible with one another. That is, the buffer layer 204 contains a cross-linking function or solvent that cannot mix with the photoresist layer 206. As explained below, a reaction is induced in portions of the buffer layer to make those portions of the buffer layer removable with the photoresist layer, i.e., dissolvable with a developer used to remove corresponding portions of the photoresist layer. The resist layer 206 is formed by a method such as spin-on coating, in one example. A soft baking may be implemented after the resist layer 206 is formed. The resist layer 206 may include chemical amplification resist (CA resist). The CA resist includes a photosensitive material referred to as photoacid generator (PAG). A photon induces decomposition of PAG and forms a small amount of acid, which further induces a cascade of chemical transformations in the resist layer, typically during a post-exposure bake (PEB) step. As will be explained further below, in one embodiment, the cascading of chemical transformations extend into the buffer layer 204 lying under the resist layer 206. In an alternate embodiment, the buffer layer 204 itself may have a PAG component that when the buffer layer is exposed to a radiation beam, acid is formed in the buffer layer 204 itself thereby rending targeted portions thereof soluble to a developing solution.

The method 100 proceeds to step 108 wherein the resist layer 206 on the substrate 202 is patterned, by a lithography process including exposing the buffer and resist layers to a radiation beam. The radiation beam may be a photon beam. For example, the resist layer on a semiconductor wafer may be exposed to an ultraviolet (UV) light through a mask (not shown) having a predefined pattern that defines desired openings. The exposing process may be implemented using a stepper by a step-and-repeat method or using a scanner by a step-and-scan method. Other options to the radiation beam other than photon beams include electron beam and ion beam. For example, the resist layer and the buffer layer may be exposed to an electron beam (e-beam) by an e-beam exposure system (e-beam writer). A pattern may be written to the resist layer according to a predefined pattern using the e-beam writer. The exposing process may be further extended to include other technologies such as a maskless exposing or writing process.

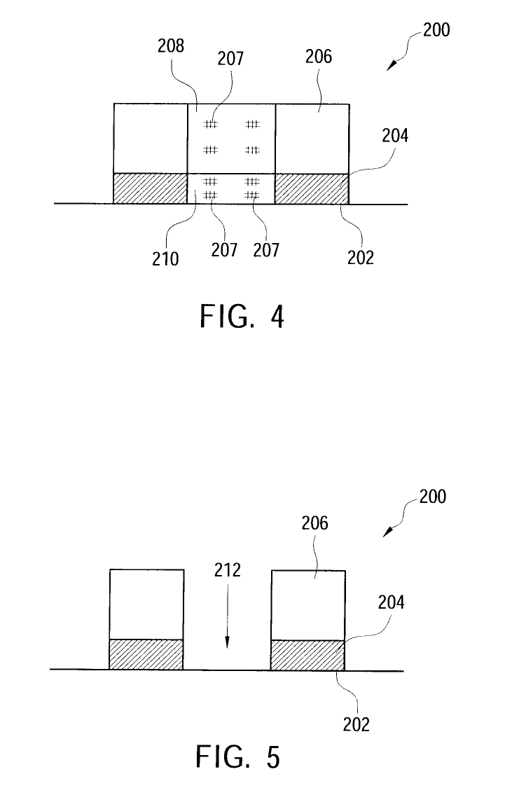

Referring to FIG. 4, after the exposing process, the resist layer 206 is further processed by a thermal baking process, referred to as a post exposure bake (PEB). The PEB may induce a cascade of chemical transformations in the exposed portion of the resist layer, i.e., in the portions of the first resist layer that is within the footprint of the desired openings defined by the patterned mask. The resist layer is thereby transformed to have an increased solubility in a developer. As referenced above, the cascade of chemical transformations, generally referenced by numeral 207, also diffuses into portions of the buffer layer that lie underneath the exposed portions of the resist layer and, as such, also within the footprint of the desired openings defined by the patterned mask. Thereafter, the resist layer 206 and the buffer layer 204 are developed such that the exposed resist portions 208 and underlying buffer portions 210 are dissolved and washed away during the developing process. In one embodiment, the same developer is used to simultaneously wash away both the exposed resist portions 207 as well as buffer layer portions 210; although, it is contemplated that two separate developers may be used. Thus the resist layer 206 and the buffer layer 204 are patterned to have one or more openings 212 as illustrated in FIG. 5. In contrast to conventionally developed resist openings, the resist openings 212 formed with the present method are substantially free of resist scum and/or footings.

The lithography processes described above may only present a subset of processing steps associated with a lithography patterning technique. The lithography process may further include other steps such as cleaning and baking in a proper sequence. For example, the developed resist and buffer layers may be further baked, referred to as hard baking.

In accordance with conventional fabrication techniques, the method 100 then proceeds to step 110 wherein the substrate 202 is etched. Thereafter, the buffer layer 204 and the resist layer 206 may be removed at 112 by a process such as wet stripping or plasma ashing.

It is recognized that a number of PAGs may be used with the present invention. For example, the commercial product referred to as TPS C4 is one exemplary PAG component that can be used to decompose the buffer layer. As such, it is recognized that other PAG components may be used, such as that described in U.S. Pat. No. 5,648,196 which discloses a water soluble photoacid generator that is formulated with a p-hydroxystyrene polymer and a water soluble sugar. In U.S. Pat. No. 5,648,196, the disclosure of which is incorporate herein by reference, one exemplary PAG component is dimethylarylsulfonium salt wherein the aryl group has one or more hydroxy constituents. Other exemplary PAG components include odium salts including diphenyliodonium salts and triphenylsulfonium salts, halogen compounds, and o-nitrobenityl esters such as 2-nitrobenzylsulfonic acid ester. One skilled in the art will appreciate that the listed PAG components usable with the present disclosure are not exhaustive and that other PAG components not specifically identified may be used. Additionally, it is recognized that the PAG component may be selected to achieve a desired diffusion length. That is, if a long diffusion length is desired, a small molecular size PAG is preferably used whereas for a short diffusion length, a bulky PAG is preferably used.

A suitable developer that may be used to remove the exposed portions of the resist and buffer layers is tetramethyl ammonium hydroxide (TMAH). However, other developers are contemplated.

It is recognized that a number of material(s) may be used for composition of the buffer layer. In one example, the buffer layer is formed of a relatively thin polymer containing Lactone, compounds with an —OH functional group, compounds with a —COOH functional group, or the like that absorb acid released by the photo-resist layer 206 in such a manner that causes affected regions of the buffer layer 204 to be dissolvable by an appropriate developer, such as TMAH.

Therefore, in one exemplary embodiment, the present invention is directed to a process of patterning a semiconductor device. The semiconductor device is patterned by depositing a thin resist or buffer layer on a substrate film followed by depositing of a photo-resist layer on the buffer layer. The photo-resist layer includes an acid generating component that is activated during exposure of the photo-resist layer. Thus, during exposure of the photo-resist layer, acid or other agent is released by the photo-resist layer and diffuses into portions of the buffer layer. The agent is absorbed by the buffer layer and decomposes affected regions of the buffer layer during post-exposure baking thereby making the affected regions dissolvable by a suitable developer that can be applied to simultaneously remove exposed portions of the photo-resist layer and the buffer layer.

It is to be understood that the following disclosure provides different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not itself dictate a relationship between various embodiments and/or configurations discussed.

What is claimed is:

1. A method of patterning an integrated circuit, comprising:
providing a base layer;
forming a buffer layer on the base layer;
forming a resist layer on the buffer layer;
inducing a reaction in a region of the buffer layer so as to make the region removable; and
removing the region of the buffer layer and a portion of the resist layer generally aligned with the region of the buffer layer with a developer.

2. The method of claim 1 wherein removing of the region of the buffer layer and the portion of the resist layer is done with the same developer.

3. The method of claim 2 wherein the developer includes TMAH.

4. The method of claim 1 wherein the buffer layer has a thickness between 30-100 Angstroms.

5. The method of claim 1 further comprising simultaneously removing the region of the buffer layer and the portion of the resist layer after a post-exposure bake.

6. The method of claim 1 wherein the reaction is induced during exposure of the resist layer.

7. The method of claim 6 wherein the resist layer includes a photoacid generator that generates acid during exposure of the portion of the resist layer which induces a cascade of chemical transformations in the portion of the resist layer during a post-exposure bake.

8. The method of claim 1 wherein the buffer layer includes a photoacid generator that generates acid during exposure of the buffer layer which induces a cascade of chemical transformations in the region of the buffer layer during a post-exposure bake.

9. The method of claim 1 further comprising defining the region of the buffer layer and the portion of the resist layer during a photo-masking step.

10. A method of patterning a substrate, comprising:
developing a first layer and a second layer in a stacked arrangement;
inducing a reaction in the first layer during exposure of the second layer so as to make regions of the first layer dissolvable by a developer; and
applying the developer to the first layer and the second layer to simultaneously remove regions of the first layer and portions of the second layer.

11. The method of claim 10 wherein the developer includes TMAH.

12. The method of claim 10 wherein the first layer includes a polymer that is in a hydrophobic state prior to inducing a reaction therein during exposure of the second layer.

13. The method of claim 12 wherein the polymer includes a bottom anti-reflective coating (BARC).

14. The method of claim 10 wherein the first layer includes a photoacid generator (PAG) that induces chemical transformations in the second layer when exposed.

15. A method of developing a pattern on a semiconductor device layer, comprising:
providing a base layer;
applying a first resist layer on the base layer;
applying a second resist layer on the first resist layer, the second resist layer being different from the first resist layer;
masking the second resist layer to demarcate boundaries of a desired opening in the first resist layer and the second resist layer;
inducing a chemical region in a portion of the first resist layer that is in a footprint of the desired opening, said chemical region making the portion of the first resist layer removable with the second resist layer; and
removing the portion of the first resist layer and a region of the second resist layer within the footprint of the desired opening with a developer to form an opening in the both the first resist layer and the second resist layer.

16. The method of claim 15 further comprising exposing the first resist layer, wherein said exposure causes formation of an acid in the second resist layer within the footprint of the desired opening, and baking the first and second resist layers, wherein said baking causes a cascading of chemical transformations in the second resist layer that diffuse into the portion of the first resist layer to make the portion of the first resist layer removable with the second resist layer.

17. The method of claim 15 wherein the first resist layer includes a BARC component.

18. The method of claim 16 wherein the first resist layer includes a PAG component that generates acid in an exposed portion of the first resist layer when the first resist layer is exposed.

19. The method of claim 15 wherein the developer is TMAH.

20. The method of claim 15 further comprising etching the base layer through the opening formed in the first and second resist layers and stripping the first resist and second resist layers defining the opening after etching of the base layer.
